(19) United States
(12) Patent Application Publication
(10) Pub. No.: US 2020/0144345 A1
(43) Pub. Date: May 7, 2020

(54) DISPLAY DEVICE AND METHOD OF MANUFACTURING THE SAME

(71) Applicant: SAMSUNG DISPLAY CO., LTD., Yongin-si (KR)

(72) Inventors: Myounggeun CHA, Yongin-si (KR); Sanggun CHOI, Yongin-si (KR); Sangsub KIM, Yongin-si (KR); Jiyeong SHIN, Yongin-si (KR); Yongsu LEE, Yongin-si (KR); Kiseok CHOI, Yongin-si (KR)

(21) Appl. No.: 16/556,484

(22) Filed: Aug. 30, 2019

(30) Foreign Application Priority Data
Nov. 5, 2018 (KR) 10-2018-0134613

(51) Int. Cl. H01L 27/32; H01L 51/56

(52) U.S. Cl. CPC H01L 27/3258; H01L 27/3265; H01L 27/3262; H01L 27/3276; H01L 2251/303; H01L 2227/323; H01L 2251/301; H01L 2251/558; H01L 51/56

(57) ABSTRACT

A display device includes a substrate, a metal layer on the substrate, a buffer layer covering the metal layer on the substrate, the buffer layer having a planarized upper surface, and including a first buffer layer including a first portion not overlapping an upper surface of the metal layer and a second portion overlapping an upper surface of the metal layer, the second portion protruding upward from the first portion from the first portion, and a second buffer layer on the first portion of the first buffer layer, an active pattern on the planarized upper surface of the buffer layer, the active pattern overlapping the metal layer, a gate insulation layer on the active pattern, a gate electrode on the gate insulation layer, the gate electrode overlapping the active pattern, and an organic light emitting diode on the gate electrode.

### CROSS-REFERENCE TO RELATED APPLICATION

Korean Patent Application No. 10-2018-0134613, filed on Nov. 5, 2018, in the Korean Intellectual Property Office, and entitled: “Display Device and Method of Manufacturing the Same,” is incorporated by reference herein in its entirety.

### BACKGROUND

### 1. Field

Embodiments relate to a display device. More particularly, embodiments relate to a display device including a thin film transistor and a method of manufacturing the display device.

### 2. Description of the Related Art

Flat panel display devices have been widely used as display devices. Among the flat display devices, an organic light emitting display device has been attracting attention due to its advantages, e.g., slim thickness, light weight, low power consumption, fast response speed, etc.

The organic light emitting display device may include a plurality of thin film transistors and an organic light emitting diode connected to the thin film transistors. The organic light emitting diode may emit light having a luminance corresponding to a voltage transmitted from the thin film transistors to the organic light emitting diode.

### SUMMARY

A display device according to embodiments may include a substrate, a metal layer on the substrate, a buffer layer covering the metal layer and being on the substrate, the buffer layer having a planarized upper surface, an active pattern on the planarized upper surface of the buffer layer, the active pattern overlapping the metal layer, a gate insulation layer on the active pattern, a gate electrode on the gate insulation layer, the gate electrode overlapping the active pattern, and an organic light emitting diode on the gate electrode. The buffer layer may include a first buffer layer including a first portion not overlapping the metal layer and a second portion overlapping the metal layer, the second portion protruding toward the active pattern from the first portion, and a second buffer layer on the first portion of the first buffer layer.

In an embodiment, a thickness of the metal layer may be greater than or equal to a thickness of the gate electrode.

In an embodiment, a material of the metal layer may be the same as a material of the gate electrode.

In an embodiment, an upper surface of the second portion of the first buffer layer and an upper surface of the second buffer layer may be at the same level over the substrate.

In an embodiment, the second buffer layer may include silicon oxide.

In an embodiment, the buffer layer may further include an etch-stop layer between the first portion of the first buffer layer and the second buffer layer and between the second portion of the first buffer layer and the active pattern.

In an embodiment, the etch-stop layer may include silicon nitride.

In an embodiment, an upper surface of the etch-stop layer disposed on the second portion of the first buffer layer and an upper surface of the second buffer layer may be at the same level over the substrate.

In an embodiment, the display device may further include a driving voltage line on the gate electrode, the driving voltage line transmitting a driving voltage to the organic light emitting diode. The metal layer may be connected to the driving voltage line.

In an embodiment, the active pattern may include a source electrode, a drain electrode, and a channel between the source electrode and the drain electrode, and the metal layer may be connected to the source electrode.

In an embodiment, the metal layer may be connected to the gate electrode.

In an embodiment, a thickness of the metal layer may be greater than or equal to about 2500 Å.

A display device according to embodiments may include a substrate, a metal layer on the substrate, a buffer layer covering the metal layer and being on the substrate, the buffer layer having a planarized upper surface, an active pattern on the planarized upper surface of the buffer layer, the active pattern overlapping the metal layer, a gate insulation layer on the active pattern, a gate electrode on the gate insulation layer, the gate electrode overlapping the active pattern, and an organic light emitting diode on the gate electrode. A thickness of a first portion of the buffer layer disposed on the metal layer may be less than a thickness of a second portion of the buffer layer not overlapping the metal layer.

In an embodiment, a thickness of the first portion of the buffer layer may be less than or equal to a thickness of the gate insulation layer.

In an embodiment, a thickness of the metal layer may be greater than or equal to a thickness of the gate electrode.

In an embodiment, a material of the metal layer may be the same as a material of the gate electrode.

In an embodiment, a thickness of the first portion of the buffer layer may be less than or equal to about 1300 Å.

A method of manufacturing a display device according to embodiments may include forming a metal layer on a substrate, forming a buffer layer on the substrate, the buffer layer covering the metal layer, and a portion of the buffer layer overlapping the metal layer being protruded, planarizing an upper surface of the buffer layer, forming an active pattern on the planarized upper surface of the buffer layer, the active pattern overlapping the metal layer, forming a gate insulation layer on the active pattern, forming a gate electrode on the gate insulation layer, the gate electrode overlapping the active pattern, and forming an organic light emitting diode on the gate electrode. Forming the buffer layer may include forming a first buffer layer on the metal layer, the first buffer layer including a first protruding portion overlapping the metal layer, and forming a second buffer layer on the first buffer layer, the second buffer layer including a second protruding portion overlapping the first protruding portion. Planarizing the upper surface of the buffer layer may include etching at least the second protruding portion.

In an embodiment, the planarizing the upper surface of the buffer layer may include etching only the second protruding portion.

In an embodiment, planarizing the upper surface of the buffer layer may include etching the second buffer layer and the first protruding portion.

In an embodiment, the upper surface of the buffer layer may be planarized by a chemical mechanical polishing.

In an embodiment, forming the buffer layer may further include forming an etch-stop layer on the first buffer layer after forming the first buffer layer and before forming the second buffer layer.

### BRIEF DESCRIPTION OF THE DRAWINGS

Features will become apparent to those of skill in the art by describing in detail exemplary embodiments with reference to the attached drawings, in which:

FIG. 1 illustrates a circuit diagram of a pixel of a display device according to an embodiment.

FIG. 2 illustrates a layout view of the pixel in FIG. 1.

FIG. 3 illustrates a cross-sectional view of a display device according to an embodiment.

FIGS. 4-6 illustrate cross-sectional views of stages in a method of manufacturing a display device according to an embodiment.

FIG. 7 illustrates a cross-sectional view of a display device according to an embodiment.

FIGS. 8-10 illustrate cross-sectional views of stages in a method of manufacturing a display device according to an embodiment.

FIG. 11 illustrates a cross-sectional view of a display device according to an embodiment.

FIGS. 12-14 illustrate cross-sectional views of stages in a method of manufacturing a display device according to an embodiment.

FIG. 15 illustrates a circuit diagram of a pixel of a display device according to an embodiment.

FIG. 16 illustrates a layout view of the pixel in FIG. 15.

FIG. 17 illustrates a circuit diagram of a pixel of a display device according to an embodiment.

FIG. 18 illustrates a layout view of the pixel in FIG. 17.

FIG. 19 illustrates a circuit diagram of a pixel of a display device according to an embodiment.

FIG. 20 illustrates a layout view of the pixel in FIG. 19.

### DETAILED DESCRIPTION

Example embodiments will now be described more fully hereinafter with reference to the accompanying drawings; however, they may be embodied in different forms and should not be construed as limited to the embodiments set forth herein. Rather, these embodiments are provided so that this disclosure will be thorough and complete, and will fully convey exemplary implementations to those skilled in the art.

In the drawing figures, the dimensions of layers and regions may be exaggerated for clarity of illustration. It will also be understood that when a layer or element is referred to as being “on” another layer or substrate, it can be directly on the other layer or substrate, or intervening layers may also be present. In addition, it will also be understood that when a layer is referred to as being “between” two layers, it can be the only layer between the two layers, or one or more intervening layers may also be present. Like reference numerals refer to like elements throughout.

Hereinafter, display devices and methods of manufacturing display devices in accordance with embodiments will be explained in detail with reference to the accompanying drawings.

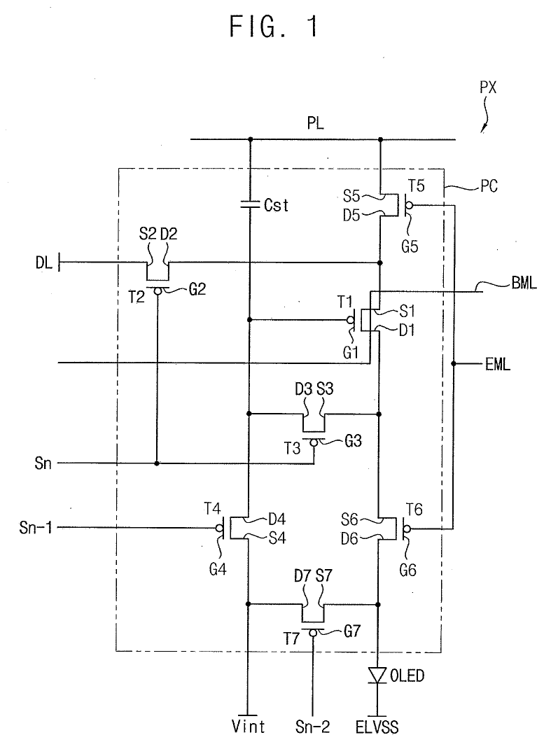

Hereinafter, a display device according to an embodiment will be described with reference to FIGS. 1 to 3.

FIG. 1 is a circuit diagram illustrating a pixel of a display device according to an embodiment.

Referring to FIG. 1, a display device according to an embodiment may include a plurality of pixels PX. Each pixel PX may include a pixel circuit PC and an organic light emitting diode OLED connected to the pixel circuit PC. The pixel circuit PC may include a plurality of thin film transistors T1, T2, T3, T4, T5, T6, and T7 and a capacitor Cst. The thin film transistors T1, T2, T3, T4, T5, T6, and T7 and the capacitor Cst may be selectively connected to a first scan line Sn, a second scan line Sn-1, a third scan line Sn-2, an emission control line EML, an initialization voltage line Vint, a data line DL, and a driving voltage line PL.

The thin film transistors T1, T2, T3, T4, T5, T6, and T7 may include a first thin film transistor T1, a second thin film transistor T2, a third thin film transistor T3, a fourth thin film transistor T4, a fifth thin film transistor T5, a sixth thin film transistor T6, and a seventh thin film transistor T7.

The first thin film transistor T1 may include a first gate electrode G1 connected to a third drain electrode D3 of the third thin film transistor T3, a fourth drain electrode D4 of the fourth thin film transistor T4, and a first electrode of the capacitor Cst; a first source electrode Si connected to a second drain electrode D2 of the second thin film transistor T2 and a fifth drain electrode D5 of the fifth thin film transistor T5; and a first drain electrode D1 connected to a third source electrode S3 of the third thin film transistor T3 and a sixth source electrode S6 of the sixth thin film transistor T6. The first thin film transistor T1 may be a driving transistor for controlling a current passing through the organic light emitting diode OLED.

The second thin film transistor T2 may include a second gate electrode G2 connected to the first scan line Sn, a second source electrode S2 connected to the data line DL, and a second drain electrode D2 connected to the first source electrode Si of the first thin film transistor Ti. The second thin film transistor T2 may be a switching transistor for turning on or turning off the first thin film transistor T1.

The third thin film transistor T3 may include a third gate electrode G3 connected to the first scan line Sn, a third source electrode S3 connected to the first drain electrode D1 of the first thin film transistor T1, and a third drain electrode D3 connected to the first gate electrode G1 of the first thin film transistor T1. The third thin film transistor T3 may be a compensation transistor for connecting between the first drain electrode D1 and the first gate electrode G1 of the first thin film transistor T1 that is the driving transistor.

The fourth thin film transistor T4 may include a fourth gate electrode G4 connected to the second scan line Sn-1, a fourth source electrode S4 connected to the initialization voltage line Vint, and a fourth drain electrode D4 connected to the first gate electrode G1 of the first thin film transistor T1. The fourth thin film transistor T4 may be an initialization transistor for initializing the first gate electrode G1 of the first thin film transistor T1 that is the driving transistor.

The fifth thin film transistor T5 may include a fifth gate electrode G5 connected to the emission control line EML, a fifth source electrode S5 connected to the driving voltage line PL, and a fifth drain electrode D5 connected to the first source electrode S1 of the first thin film transistor T1.

The sixth thin film transistor T6 may include a sixth gate electrode G6 connected to the emission control line EML, a sixth source electrode S6 connected to the first drain electrode D1 of the first thin film transistor T1, and a sixth drain electrode D6 connected to the organic light emitting diode OLED. The first thin film transistor T1 may be connected to the organic light emitting diode OLED through the sixth thin film transistor T6. The fifth thin film transistor T5 and the sixth thin film transistor T6 may be emission control transistors for connecting the first thin film transistor T1 that is the driving transistor to the driving voltage line PL and the organic light emitting diode OLED.

The seventh thin film transistor T7 may include a seventh gate electrode G7 connected to the third scan line Sn-2, a seventh source electrode S7 connected to the organic light emitting diode OLED, and a seventh drain electrode D7 connected to the fourth source electrode S4 of the fourth thin film transistor T4.

A metal layer BML may pass through at least one thin film transistor of the thin film transistors T1, T2, T3, T4, T5, T6, and T7. Specifically, the metal layer BML may overlap an active pattern of the at least one thin film transistor. In an embodiment, the metal layer BML may pass through the first thin film transistor T1. Specifically, the metal layer BML may traverse the pixel circuit PC, and may overlap the active pattern of the first thin film transistor T1.

In an embodiment, the metal layer BML may be connected to a power source located outside the pixel PX. A voltage may be provided to the metal layer BML from the power source.

The capacitor Cst may include the first electrode connected to the first gate electrode G1 of the first thin film transistor T1 and the third drain electrode D3 of the third thin film transistor T3, and a second electrode connected to the driving voltage line PL.

The organic light emitting diode OLED may include a first electrode, a second electrode located on the first electrode, and an organic emission layer located between the first electrode and the second electrode. The first electrode of the organic light emitting diode OLED may be connected to the seventh source electrode S7 of the seventh thin film transistor T7 and the sixth drain electrode D6 of the sixth thin film transistor T6, and the second electrode of the organic light emitting diode OLED may be electrically connected to a power source for supplying a common voltage ELVSS.

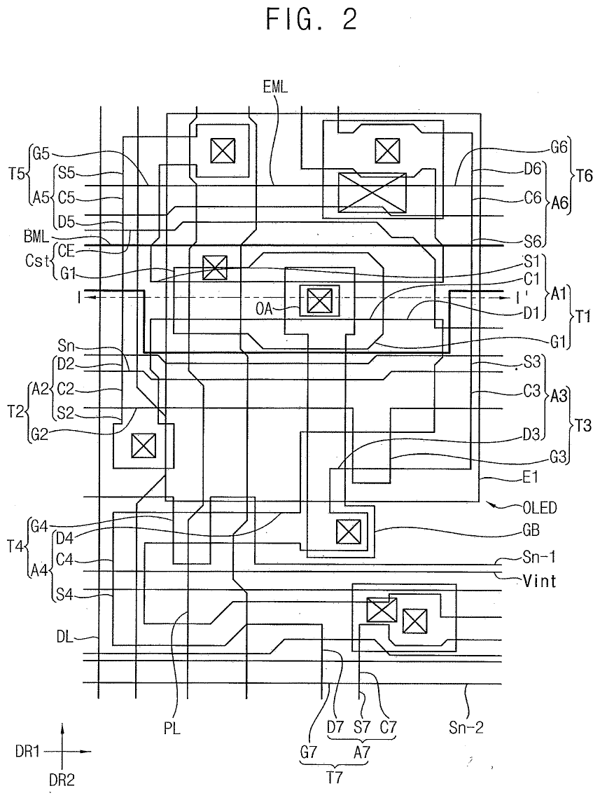

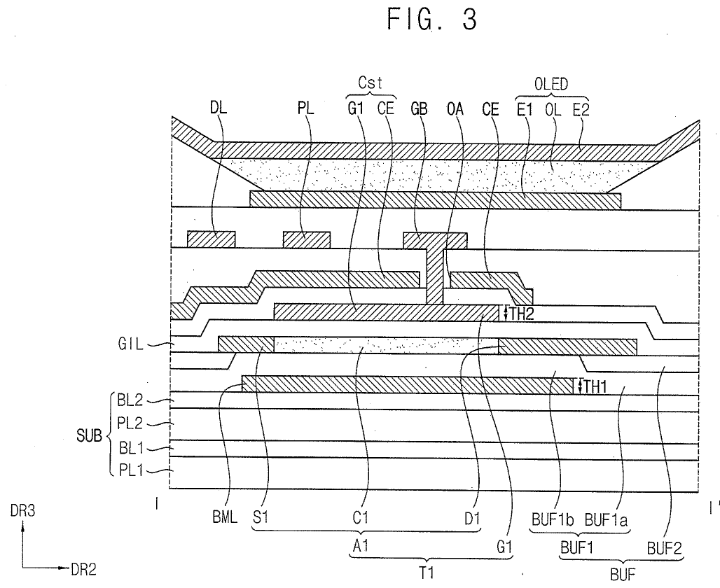

FIG. 2 is a layout view illustrating the pixel PX in FIG. 1. FIG. 3 is a cross-sectional view illustrating a display device according to an embodiment. For example, FIG. 3 may illustrate an example of the display device taken along line I-I′ in FIG. 2.

Insulation layers may be located between constituent elements positioned on different layers, and the insulation layers may be inorganic insulation layers, e.g., silicon nitride or silicon oxide, or organic insulation layers. The insulation layers may be provided as a single layer or multiple layers.

Referring to FIGS. 2 and 3, a display device according to an embodiment may include the pixel circuit PC (FIG. 1) including the first thin film transistor T1, the second thin film transistor T2, the third thin film transistor T3, the fourth thin film transistor T4, the fifth thin film transistor T5, the sixth thin film transistor T6, the seventh thin film transistor T7, the capacitor Cst, and a gate bridge GB selectively connected to the first scan line Sn, the second scan line Sn-1, the third scan line Sn-2, the emission control line EML, the data line DL, the driving voltage line PL, and the initialization voltage line Vint, and the organic light emitting diode OLED connected to the pixel circuit PC.

A substrate SUB may be an insulating substrate including, e.g., glass, polymer, or stainless steel. In an embodiment, the substrate SUB may include a first plastic layer PL1, a first barrier layer BL1, a second plastic layer PL2, and a second barrier layer BL2, which are sequentially stacked. For example, the first and second plastic layers PL1 and PL2 may include plastic, e.g., polyimide (PI), polyethylene naphthalate (PEN), polyethylene terephthalate (PET), polyarylate (PAR), polycarbonate (PC), polyetherimide (PEI), polyethersulfone (PS), or the like. The first and second barrier layers BL1 and BL2 may include silicon compounds, e.g., amorphous silicon (a-Si), silicon oxide (SiOₓ), silicon nitride (SiNₓ), or the like.

The metal layer BML (e.g., a metal line) may be disposed on the substrate SUB. The metal layer BML may traverse the pixel circuit, and may extend along a first direction DR1. For example, as illustrated in FIG. 2, the metal layer BML may extend along the first direction DR1 and have a predetermined width in a second direction DR2 (e.g., between the two thick solid lines) to overlap the first gate G1 of the first transistor T1. As illustrated in FIG. 3, the metal layer BML may overlap the first thin film transistor T1, and may be located between the substrate SUB and the first thin film transistor T1. In an embodiment, the metal layer BML may include a metal, e.g., molybdenum (Mo), or the like. The metal layer BML may be connected to a power source located outside the pixel PX through a connecting line located outside the pixel PX.

As further illustrated in FIG. 3, a buffer layer BUF covering the metal layer BML may be disposed on the substrate SUB. The buffer layer BUF may prevent impurities, e.g., oxygen, moisture, etc., from permeating through the substrate SUB. The buffer layer BUF may have a planarized upper surface. Therefore, the buffer layer BUF may provide a planarized surface on the substrate SUB. The buffer layer BUF may include a first buffer layer BUF1 and a second buffer layer BUF2.

The first buffer layer BUF1 covering the metal layer BML may be disposed on the substrate SUB. The first buffer layer BUF1 may be formed on the substrate SUB along a profile of the substrate SUB and the metal layer BML. The first buffer layer BUF1 may include a first portion BUF1a that does not overlap an upper surface of the metal layer BML and a second portion BUF1b that protrudes upward from the first portion BUF1a along a profile, e.g., along side and upper surfaces, of the metal layer BML, e.g., the first and second portions BUF1a and BUF1b may be continuous with each other to define a single layer. The first portion BUF1a of the first buffer layer BUF1 may be disposed, e.g., directly, on an upper surface of the substrate SUB, and the second portion BUF1b of the first buffer layer BUF1 may be disposed, e.g., directly, on an upper surface of the metal layer BML. Therefore, a stepped portion may be formed between the first portion BUF1a and the second portion BUF1b of the first buffer layer BUF1.

The first buffer layer BUF1 may include an inorganic insulation material, e.g., silicon nitride (SiNO, silicon oxide (SiOx), or the like. In an embodiment, the first buffer layer BUF1 may have a multilayer structure including a silicon nitride layer and a silicon oxide layer disposed on the silicon nitride layer. In an embodiment, a thickness of the first buffer layer BUF1 may be about 3500 Å.

The second buffer layer BUF2 may be disposed on the first portion BUF1a of the first buffer layer BUF1. For example, as illustrated in FIG. 3, the second buffer layer BUF2 may fill the stepped portion between the first portion BUF1a and the second portion BUF1b of the first buffer layer BUF1. The second buffer layer BUF2 may not be located on, e.g., an upper surface of, the second portion BUF1b of the first buffer layer BUF1. Therefore, the second buffer layer BUF2 may not overlap the metal layer BML.

An upper surface of the second portion BUF1b of the first buffer layer BUF1 and an upper surface of the second buffer layer BUF2 may be located on the same level over the substrate SUB, e.g., upper surfaces of the second portion BUF1b of the first buffer layer BUF1 and the second buffer layer BUF2 may be coplanar. The upper surface of the second portion BUF1b of the first buffer layer BUF1 and the upper surface of the second buffer layer BUF2 may correspond to, e.g., form, an upper surface of the buffer layer BUF. Therefore, the buffer layer BUF may have a planarized upper surface.

In an embodiment, the second buffer layer BUF2 may include, e.g., silicon oxide (SiOₓ). The second buffer layer BUF2 including the silicon oxide may be in contact with the silicon oxide layer of the first buffer layer BUF1 at an interface between the first buffer layer BUF1 and the second buffer layer BUF2.

A portion of the buffer layer BUF overlapping the metal layer BML may have a single-layer structure including the first buffer layer BUF1, and a portion of the buffer layer BUF not overlapping the metal layer BML may have a multilayer structure including the first buffer layer BUF1 and the second buffer layer BUF2. Although the second portion BUF1b of the first buffer layer BUF1 may protrude toward an upper direction from the first portion BUF1a of the first buffer layer BUF1 according to a profile of the metal layer BML, the second buffer layer BUF2 may be disposed on the first portion BUF1a of the first buffer layer BUF1 thereby planarizing the upper surface of the buffer layer BUF.

The first thin film transistor T1 may be located, e.g., directly, on the buffer layer BUF, and may include a first active pattern A1 and the first gate electrode G1. The first active pattern A1 may include the first source electrode S1, a first channel C1, and the first drain electrode D1. The first source electrode S1 may be connected to the second drain electrode D2 of the second thin film transistor T2 and the fifth drain electrode D5 of the fifth thin film transistor T5. The first drain electrode D1 may be connected to the third source electrode S3 of the third thin film transistor T3 and the sixth source electrode S6 of the sixth thin film transistor T6.

The first active pattern A1 may be disposed on the buffer layer BUF having a planarized upper surface, and may overlap the metal layer BML. For example, a lower surface of the first active pattern A1 may be in contact with the upper surface of the second portion BUF1b of the first buffer layer BUF1 and the upper surface of the second buffer layer BUF2.

The first active pattern A1 may be formed of, e.g., a polysilicon or an oxide semiconductor. The first channel C1 of the first active pattern A1 may be a channel doped with an N-type impurity or a P-type impurity. The first source electrode S1 and the first drain electrode D1 may be spaced apart from each other with the first channel C1 interposed therebetween, and may be doped with an opposite type of impurity to that with which the first channel C1 is doped.

The first channel C1 of the first active pattern A1 may overlap the metal layer BML. Since a voltage is supplied to the metal layer BML such that electric charges (e.g., electrons or holes) may be stored in the first channel C1 of the first active pattern A1 depending on a polarity of the voltage supplied to the metal layer BML, a threshold voltage of the first thin film transistor T1 may be controlled. In other words, the threshold voltage of the first thin film transistor T1 may be decreased or increased using the metal layer BML, and a driving range of the first thin film transistor T1 may vary by controlling the threshold voltage of the first thin film transistor T1.

The first gate electrode G1 may overlap the first active pattern A1, may be located on the first active pattern A1, and may have an island shape. Specifically, the first gate electrode G1 may overlap the first channel C1 of the first active pattern A1. The first gate electrode G1 may be connected to the fourth drain electrode D4 of the fourth thin film transistor T4 and the third drain electrode D3 of the third thin film transistor T3 by the gate bridge GB passing through a contact hole. The first gate electrode G1 may overlap a capacitor electrode CE. The first gate electrode G1 may function as a gate electrode of the first thin film transistor T1, and may also function as an electrode of the capacitor Cst. In other words, the first gate electrode G1 may configure the capacitor Cst together with the capacitor electrode CE.

The metal layer BML may function as a gate electrode of the first thin film transistor T1 together with the first gate electrode G1. The first thin film transistor T1 may be a double gate type thin film transistor having the metal layer BML as a lower gate electrode and the first gate electrode G1 as an upper gate electrode.

In an embodiment, a thickness TH1 of the metal layer BML may be greater than or equal to a thickness TH2 of the first gate electrode G1, e.g., along a third direction DR3. For example, the thickness TH2 of the first gate electrode G1 may be about 2500 Å, and the thickness TH1 of the metal layer BML may be greater than or equal to about 2500 Å. Since the thickness TH1 of the metal layer BML is greater than or equal to the thickness TH2 of the first gate electrode G1, the metal layer BML may have a relatively thick thickness. Therefore, electrical resistance of the metal layer BML may not be great, and delay of signal transmitted through the metal layer BML may be prevented.

In an embodiment, a material of the metal layer BML may be the same as a material of the first gate electrode G1. For example, the first gate electrode G1 and the metal layer BML may include molybdenum (Mo).

A gate insulation layer GIL may be disposed between the first active pattern A1 and the first gate electrode G1. The gate insulation layer GIL covering the first active pattern A1 may be disposed on the buffer layer BUF. The gate insulation layer GIL may insulate the first gate electrode G1 from the first active pattern A1. The gate insulation layer GIL may include an inorganic insulation material, e.g., silicon nitride (SiNₓ), silicon oxide (SiOₓ), or the like. In an embodiment, a thickness of the gate insulation layer GIL, e.g., along the third direction DR3, may be in a range from about 1200 Å to about 1300 Å.

The second thin film transistor T2 may be located on the buffer layer BUF, and may include a second active pattern A2 and the second gate electrode G2. The second active pattern A2 may include the second source electrode S2, a second channel C2, and the second drain electrode D2. The second source electrode S2 may be connected to the data line DL through a contact hole, and the second drain electrode D2 may be connected to the first source electrode S1 of the first thin film transistor T1. The second channel C2 that is a channel region of the second active pattern A2 overlapping the second gate electrode G2 may be located between the second source electrode S2 and the second drain electrode D2. The second active pattern A2 may be connected to the first active pattern A1.

The second channel C2 of the second active pattern A2 may be a channel doped with an N-type impurity or a P-type impurity. The second source electrode S2 and the second drain electrode D2 may be spaced apart from each other with the second channel C2 therebetween, and may be doped with an opposite type of impurity to that with which the second channel C2 is doped. The second active pattern A2 may be located on the same layer as the first active pattern A1, may be formed of the same material as the first active pattern A1, and may be integrally formed with the first active pattern A1. The second gate electrode G2 may be located on the gate insulation layer GIL, may overlap the second channel C2 of the second active pattern A2, and may be integrally formed with the first scan line Sn.

The third thin film transistor T3 may be located on the buffer layer BUF, and may include a third active pattern A3 and the third gate electrode G3. The third active pattern A3 may include the third source electrode S3, a third channel C3, and the third drain electrode D3. The third source electrode S3 may be connected to the first drain electrode D1, and the third drain electrode D3 may be connected to the first gate electrode G1 of the first thin film transistor T1 by the gate bridge GB passing through the contact hole. The third channel C3 that is a channel region of the third active pattern A3 overlapping the third gate electrode G3 may be located between the third source electrode S3 and the third drain electrode D3. The third active pattern A3 may connect between the first active pattern A1 and the first gate electrode G1.

The third channel C3 of the third active pattern A3 may be a channel doped with an N-type impurity or a P-type impurity. The third source electrode S3 and the third drain electrode D3 may be spaced apart from each other with the third channel C3 therebetween, and may be doped with an opposite type of impurity to that with which the third channel C3 is doped. The third active pattern A3 may be located on the same layer as, formed of the same material as, and integrally formed with the first and second active patterns A1 and A2. The third gate electrode G3 may be located on the gate insulation layer GIL, may overlap the third channel C3 of the third active pattern A3, and may be integrally formed with the first scan line Sn. The third gate electrode G3 may be Ruined as a dual-gate electrode.

The fourth thin film transistor T4 may be located on the buffer layer BUF, and may include a fourth active pattern A4 and the fourth gate electrode G4. The fourth active pattern A4 may include the fourth source electrode S4, a fourth channel C4, and the fourth drain electrode D4. The fourth source electrode S4 may be connected to the initialization voltage line Vint through a contact hole, and the fourth drain electrode D4 may be connected to the first gate electrode G1 of the first thin film transistor T1 through the gate bridge GB passing through the contact hole. The fourth channel C4 that is a channel region of the fourth active pattern A4 overlapping the fourth gate electrode G4 may be located between the fourth source electrode S4 and the fourth drain electrode D4. The fourth active pattern A4 may connect between the initialization voltage line Vint and the first gate electrode G1, and may be connected to the third active pattern A3 and the first gate electrode G1.

The fourth channel C4 of the fourth active pattern A4 may be a channel doped with an N-type impurity or a P-type impurity. The fourth source electrode S4 and the fourth drain electrode D4 may be spaced apart from each other with the fourth channel C4 therebetween, and may be doped with an opposite type of impurity to that with which the fourth channel C4 is doped. The fourth active pattern A4 may be located on the same layer as, formed of the same material as, and integrally formed with the first, second, and third active patterns A1, A2, and A3. The fourth gate electrode G4 may be located on the gate insulation layer GIL, may overlap the fourth channel C4 of the fourth active pattern A4, and may be integrally formed with the second scan line Sn-1. The fourth gate electrode G4 may be formed to be a dual-gate electrode.

The fifth thin film transistor T5 may be located on the buffer layer BUF, and may include a fifth active pattern A5 and the fifth gate electrode G5. The fifth active pattern A5 may include the fifth source electrode S5, a fifth channel C5, and the fifth drain electrode D5. The fifth source electrode S5 may be connected to the driving voltage line PL through a contact hole, and the fifth drain electrode D5 may be connected to the first source electrode S1 of the first thin film transistor T1. The fifth channel C5 that is a channel region of the fifth active pattern A5 overlapping the fifth gate electrode G5 may be located between the fifth source electrode S5 and the fifth drain electrode D5. The fifth active pattern A5 may connect between the driving voltage line PL and the first active pattern A1.

The fifth channel C5 of the fifth active pattern A5 may be a channel doped with an N-type impurity or a P-type impurity. The fifth source electrode S5 and the fifth drain electrode D5 may be spaced apart from each other with the fifth channel C5 therebetween, and may be doped with an opposite type of impurity to that with which the fifth channel C5 is doped. The fifth active pattern A5 may be located on the same layer as, formed of the same material as, and integrally formed with the first to fourth active patterns A1, A2, A3, and A4. The fifth gate electrode G5 may be located on the gate insulation layer GIL, may overlap the fifth channel C5 of the fifth active pattern A5, and may be integrally formed with the emission control line EML.

The sixth thin film transistor T6 may be located on the buffer layer BUF, and may include a sixth active pattern A6 and the sixth gate electrode G6. The sixth active pattern A6 may include the sixth source electrode S6, a sixth channel C6, and the sixth drain electrode D6. The sixth source electrode S6 may be connected to the first drain electrode D1 of the first thin film transistor T1, and the sixth drain electrode D6 may be connected to a first electrode E1 of the organic light emitting element OLED through a contact hole. The sixth channel C6 that is a channel region of the sixth active pattern A6 overlapping the sixth gate electrode G6 may be located between the sixth source electrode S6 and the sixth drain electrode D6. The sixth active pattern A6 may connect between the first active pattern A1 and the first electrode E1 of the organic light emitting element OLED.

The sixth channel C6 of the sixth active pattern A6 may be a channel doped with an N-type impurity or a P-type impurity. The sixth source electrode S6 and the sixth drain electrode D6 may be spaced apart from each other with the sixth channel C6 therebetween, and may be doped with an opposite type of impurity to that with which the sixth channel C6 is doped. The sixth active pattern A6 may be located on the same layer as, formed of the same material as, and integrally formed with the first to fifth active patterns A1, A2, A3, A4, and A5. The sixth gate electrode G6 may be located on the gate insulation layer GIL, may overlap the sixth channel C6 of the sixth active pattern A6, and may be integrally formed with the emission control line EML.

The seventh thin film transistor T7 may be located on the buffer layer BUF, and may include a seventh active pattern A7 and the seventh gate electrode G7. The seventh active pattern A7 may include the seventh source electrode S7, a seventh channel C7, and the seventh drain electrode D7. The seventh source electrode S7 may be connected to a first electrode of an organic light emitting element OLED of another pixel (that may be another pixel located on a bottom portion of the pixel shown in FIG. 2) that is not shown in FIG. 3, and the seventh drain electrode D7 may be connected to the fourth source electrode S4 of the fourth thin film transistor T4. The seventh channel C7 that is a channel region of the seventh active pattern A7 overlapping the seventh gate electrode G7 may be located between the seventh source electrode S7 and the seventh drain electrode D7. The seventh active pattern A7 may connect between the first electrode of the organic light emitting element OLED and the fourth active pattern A4.

The seventh channel C7 of the seventh active pattern A7 may be a channel doped with an N-type impurity or a P-type impurity. The seventh source electrode S7 and the seventh drain electrode D7 may be spaced apart from each other with the seventh channel C7 therebetween, and may be doped with an opposite type of impurity to that with which the seventh channel C7 is doped. The seventh active pattern A7 may be located on the same layer as, formed of the same material as, and integrally formed with the first to sixth active patterns A1, A2, A3, A4, A5, and A6. The seventh gate electrode G7 may be located on the gate insulation layer GIL, may overlap the seventh channel C7 of the seventh active pattern A7, and may be integrally formed with the third scan line Sn-2.

The first scan line Sn may be located on the second active pattern A2 and the third active pattern A3 to be extended in a direction (e.g., the first direction DR1) traversing the second active pattern A2 and the third active pattern A3. The first scan line Sn may be integrally formed with the second gate electrode G2 and the third gate electrode G3 to be connected to the second gate electrode G2 and the third gate electrode G3.

The second scan line Sn-1 may be separated from the first scan line Sn to be located on the fourth active pattern A4, and may be extended in a direction (e.g., the first direction DR1) traversing the fourth active pattern A4. The second scan line Sn-1 may be integrally formed with the fourth gate electrode G4 to be connected to the fourth gate electrode G4.

The third scan line Sn-2 may be separated from the second scan line Sn-1 to be located on the seventh active pattern A7, and may be extended in a direction (e.g., the first direction DR1) traversing the seventh active pattern A7. The third scan line Sn-2 may be integrally formed with the seventh gate electrode G7 to be connected to the seventh gate electrode G7.

The emission control line EML may be separated from the first scan line Sn to be located on the fifth active pattern A5 and the sixth active pattern A6, and may be extended in a direction (e.g., the first direction DR1) traversing the fifth active pattern A5 and the sixth active pattern A6. The emission control line EML may be integrally formed with the fifth gate electrode G5 and the sixth gate electrode G6 to be connected to the fifth gate electrode G5 and the sixth gate electrode G6.

The above-described emission control line EML, the third scan line Sn-2, the second scan line Sn-1, the first scan line Sn, the first gate electrode G1, the second gate electrode G2, the third gate electrode G3, the fourth gate electrode G4, the fifth gate electrode G5, the sixth gate electrode G6, and the seventh gate electrode G7 may be located on the same layer, and may be formed of the same material. For example, the emission control line EML, the third scan line Sn-2, the second scan line Sn-1, the first scan line Sn, the first gate electrode G1, the second gate electrode G2, the third gate electrode G3, the fourth gate electrode G4, the fifth gate electrode G5, the sixth gate electrode G6, and the seventh gate electrode G7 may be located on the gate insulation layer GIL, and may be formed of molybdenum (Mo).

The capacitor Cst may include a first electrode and a second electrode facing each other with an insulation layer therebetween. The first electrode may be the capacitor electrode CE, and the second electrode may be the first gate electrode G1. The capacitor electrode CE may be located on the first gate electrode G1, and may be connected to the driving voltage line PL through a contact hole. The capacitor electrode CE may configure the capacitor Cst together with the first gate electrode G1, and the first gate electrode G1 and the capacitor electrode CE may be formed of different metals or the same metal at different layers.

The capacitor electrode CE may include an opening OA overlapping a portion of the first gate electrode G1, and the gate bridge GB may be connected to the first gate electrode G1 through the opening OA. The capacitor electrode CE may overlap the metal layer BML.

The data line DL may be located on the first scan line Sn to be extended in a direction (e.g., the second direction DR2) traversing the first scan line Sn, and may be connected to the second source electrode S2 of the second active pattern A2 through a contact hole. The data line DL may be extended to traverse the first scan line Sn, the second scan line Sn-1, the third scan line Sn-2, and the emission control line EML.

The driving voltage line PL may be separated from the data line DL to be provided on the first scan line Sn, and may be extended in a direction (e.g., the second direction DR2) traversing the first scan line Sn. The driving voltage line PL may be connected to the capacitor electrode CE and the fifth source electrode S5 of the fifth active pattern A5 connected to the first active pattern A1 through contact holes. The driving voltage line PL may be extended to traverse the first scan line Sn, the second scan line Sn-1, the third scan line Sn-2, and the emission control line EML.

The gate bridge GB may be located on the first scan line Sn to be spaced from the driving voltage line PL. The gate bridge GB may be connected to the third drain electrode D3 of the third active pattern A3 and the fourth drain electrode D4 of the fourth active pattern A4 through a contact hole, and may be connected to the first gate electrode G1 exposed by the opening OA of the capacitor electrode CE through another contact hole.

The above-described data line DL, the driving voltage line PL, and the gate bridge GB may be located on the same layer, and may be formed of the same material. In another embodiment, the data line DL, the driving voltage line PL, and the gate bridge GB may be selectively located on different layers, and may be formed of different materials.

The initialization voltage line Vint may be located on the second scan line Sn-1, and may be connected to the fourth source electrode S4 of the fourth active pattern A4 through the contact hole. The initialization voltage line Vint may be located on the same layer as the first electrode E1 of the organic light emitting element OLED, and may be formed of the same material. In another embodiment, the initialization voltage line Vint may be located on a different layer and formed of a different material from the first electrode E1.

The organic light emitting element OLED may include the first electrode E1, an organic emission layer OL, and a second electrode E2. The first electrode E1 may be connected to the sixth drain electrode D6 of the sixth thin film transistor T6 through a contact hole. The organic emission layer OL may be located between the first electrode E1 and the second electrode E2. The second electrode E2 may be located on the organic emission layer OL. At least one of the first electrode E1 and the second electrode E2 may be any one of a light transmittable electrode, a light reflective electrode, and a light semi-transmittable electrode, and the light emitted from the organic emission layer OL may be output in at least one electrode direction of the first electrode E1 and the second electrode E2.

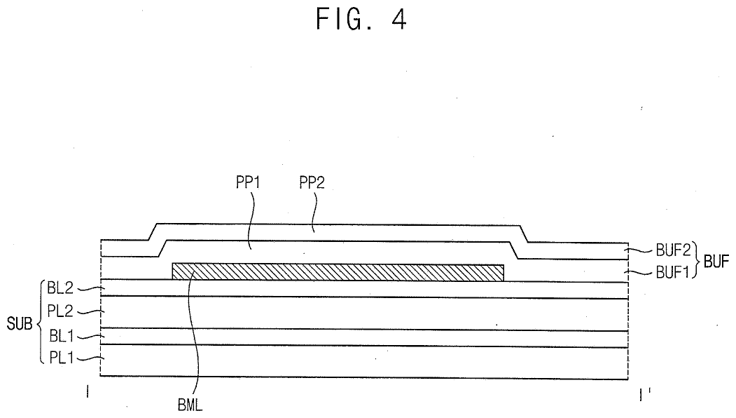

Hereinafter, a method of manufacturing a display device according to an embodiment will be described with reference to FIGS. 3 to 6. FIGS. 4-6 are cross-sectional views illustrating stages in a method of manufacturing the display device of FIG. 3.

Referring to FIG. 4, the metal layer BML and the buffer layer BUF may be formed on the substrate SUB. For example, a layer including metal, e.g., molybdenum (Mo), may be deposited by chemical vapor deposition (CVD), sputtering, etc., on the substrate SUB, and the layer including the metal may be patterned to form the metal layer BML.

Then, the buffer layer BUF covering the metal layer BML may be formed on the substrate SUB. The first buffer layer BUF1 may be deposited on the metal layer BML. The first buffer layer BUF1 may be deposited on the substrate SUB and along a profile of the substrate SUB and the metal layer BML, e.g., the first buffer layer BUF1 may cover an exposed upper surface of the substrate SUB and exposed side and upper surfaces of the metal layer BML. Accordingly, the first buffer layer BUF1 may include a first protruding portion PP1 protruding upward, e.g., relative to a portion of the first buffer layer BUF1 directly on the substrate SUB, along a profile of the metal layer BML. The first protruding portion PP1 may overlap the metal layer BML. For example, a silicon nitride layer and a silicon oxide layer may be sequentially deposited by chemical vapor deposition (CVD), sputtering, etc., on the substrate SUB on which the metal layer BML is formed to form the first buffer layer BUF1.

Then, the second buffer layer BUF2 may be deposited on the first buffer layer BUF1. The second buffer layer BUF2 may be deposited on the first buffer layer BUF1 along a profile of the first buffer layer BUF1. Accordingly, the second buffer layer BUF2 may include a second protruding portion PP2 protruding upward along a profile of the first protruding portion PP1. The second protruding portion PP2 may overlap the first protruding portion PP1. For example, a silicon oxide layer may be deposited by chemical vapor deposition (CVD), sputtering, etc., on the first buffer layer BUF1 to form the second buffer layer BUF2. Therefore, a buffer layer BUF in which a portion overlapping the metal layer BML is protruded may be formed.

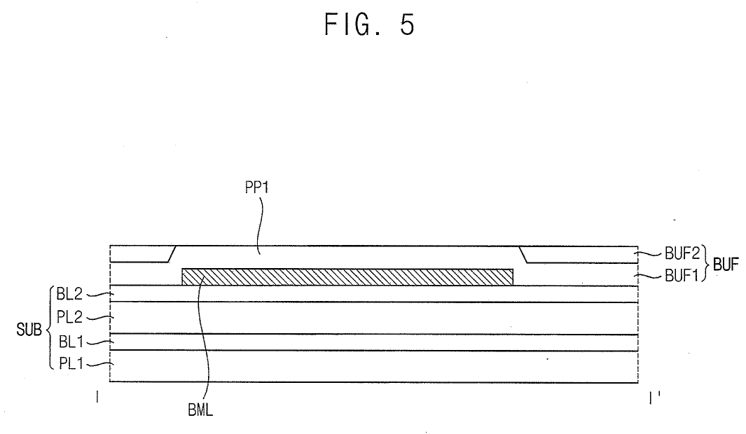

Referring to FIG. 5, an upper surface of the buffer layer BUF may be planarized. At least the second protruding portion PP2 of the second buffer layer BUF2 may be etched, e.g., removed, to planarize the upper surface of the buffer layer BUF, e.g., so upper surfaces of the first and second buffer layers BUF1 and BUF2 remaining on the substrate SUB are level with each other to define a single flat surface.

In an embodiment, only the second protruding portion PP2 may be etched to planarize the upper surface of the buffer layer BUF. In the buffer layer BUF, only the second protruding portion PP2 protruding upward may be etched, and a remaining portion of the buffer layer BUF may not be etched. In other words, in the second buffer layer BUF2, only the second protruding portion PP2 may be etched, and a remaining portion of the second buffer layer BUF2 and an entirety of the first buffer layer BUF1 may not be etched. The buffer layer BUF may be etched down from the upper surface of the second protruding portion PP2 by a thickness of the second buffer layer BUF2, and the first protruding portion PP1 of the first buffer layer BUF1 may not be etched.

In an embodiment, an entirety of the second protruding portion PP2 and a portion of the first protruding portion PP1 may be etched to planarize the upper surface of the buffer layer BUF. In the second buffer layer BUF2, the second protruding portion PP2 protruding upward as well as an upper part of a remaining portion of the second buffer layer BUF2 may be etched, and in the first buffer layer BUF1, an upper part of the first protruding portion PP1 may be etched. The buffer layer BUF may be etched down from the upper surface of the second protruding portion PP2 by a thickness greater than a thickness of the second buffer layer BUF2 and less than an addition of a thickness of the first buffer layer BUF1 and a thickness of the second buffer layer BUF2.

In an embodiment, the upper surface of the buffer layer BUF may be planarized by chemical mechanical polishing.

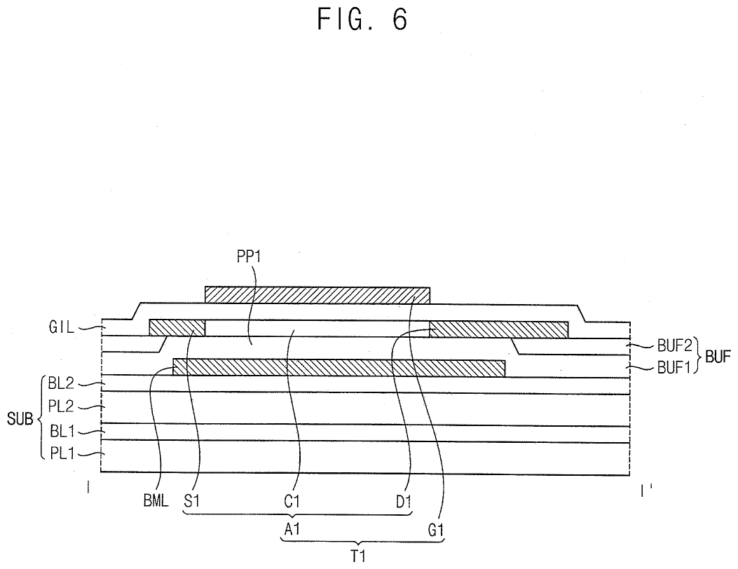

Referring to FIG. 6, the active patterns A1, A2, A3, A4, A5, A6, and A7, the gate insulation layer GIL, and the gate electrodes G1, G2, G3, G4, G5, G6, and G7 may be formed on the buffer layer BUF having the planarized upper surface.

The active patterns A1, A2, A3, A4, A5, A6, and A7 may be formed on the planarized buffer layer BUF. For example, an amorphous silicon layer may be deposited on the buffer layer BUF by chemical vapor deposition (CVD), sputtering, etc., and the amorphous silicon layer may be crystallized by an excimer laser, etc. to form a polycrystalline silicon layer. The polycrystalline silicon layer may be patterned to form the active patterns A1, A2, A3, A4, A5, A6, and A7.

The first active pattern A1 among the active patterns A1, A2, A3, A4, A5, A6, and A7 may be formed on the planarized upper surface of the buffer layer BUF to overlap the metal layer BML. For example, a lower surface of the first active pattern A1 may be in contact with an upper surface of the first protruding portion PP1 of the first buffer layer BUF1 and an upper surface of the second buffer layer BUF2. The first active pattern A1 may be formed on the planarized upper surface of the buffer layer BUF such that the first active pattern A1 may not have a stepped portion.

In a comparative example, when a buffer layer has a stepped portion, an amorphous silicon layer formed on the buffer layer may be ununiformly crystallized during a crystallizing process using a laser. Therefore, characteristics of such an active pattern having a non-uniform crystallization may deteriorate. However, in the present embodiment, the upper surface of the buffer layer BUF having a stepped portion may be planarized, such that the amorphous silicon layer may be deposited on the planarized buffer layer BUF, thereby facilitating uniform crystallization of the amorphous silicon layer and subsequent formation of the first active pattern A1 with improved characteristics.

Then, the gate insulation layer GIL may be formed on the active patterns A1, A2, A3, A4, A5, A6, and A7. For example, a silicon nitride layer and/or a silicon oxide layer may be deposited on the buffer layer BUF on which the active patterns A1, A2, A3, A4, A5, A6, and A7 are formed by chemical vapor deposition (CVD), sputtering, etc. to form the gate insulation layer GIL.

Then, the gate electrodes G1, G2, G3, G4, G5, G6, and G7 respectively overlapping the active patterns A1, A2, A3, A4, A5, A6, and A7 may be formed on the gate insulation layer GIL. For example, a layer including metal, e.g., molybdenum (Mo), etc., may be deposited on the substrate SUB by chemical vapor deposition (CVD), sputtering, etc., and the layer including the metal may be patterned to form the gate electrodes G1, G2, G3, G4, G5, G6, and G7. Impurities may be doped at opposite ends of each of the active patterns A1, A2, A3, A4, A5, A6, and A7 using the gate electrodes G1, G2, G3, G4, G5, G6, and G7 as a mask to form the source electrodes S1, S2, S3, S4, S5, S6, and S7 and the drain electrodes D1, D2, D3, D4, D5, D6, and D7. Therefore, the thin film transistors T1, T2, T3, T4, T5, T6, and T7 respectively including the active patterns A1, A2, A3, A4, A5, A6, and A7 and the gate electrodes G1, G2, G3, G4, G5, G6, and G7 may be formed on the buffer layer BUF.

Referring to FIG. 3, the organic light emitting diode OLED may be formed on the substrate SUB on which the thin film transistors T1, T2, T3, T4, T5, T6, and T7 are formed. The capacitor electrode CE, the data line DL, the driving voltage line PL, the gate bridge GB, etc. and the insulation layers interposed therebetween may be formed on the thin film transistors T1, T2, T3, T4, T5, T6, and T7, and the first electrode E1, the organic emission layer OL, and the second electrode E2 may be sequentially deposited to form the organic light emitting diode OLED.

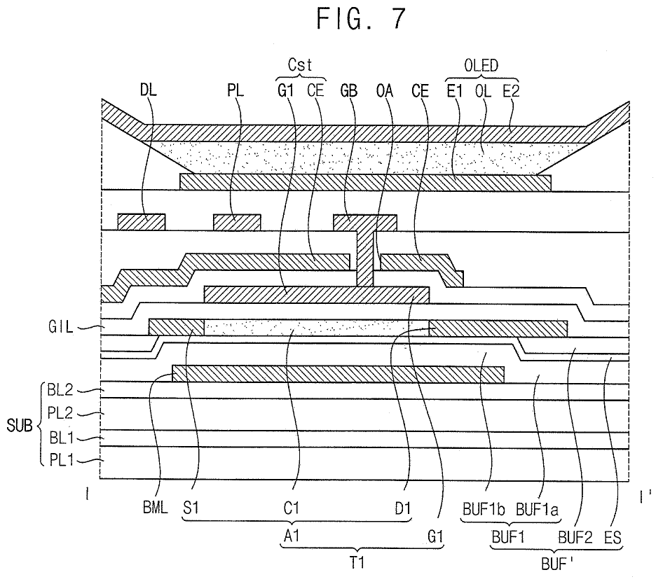

Hereinafter, a display device according to an embodiment will be described with reference to FIG. 7.

FIG. 7 is a cross-sectional view illustrating a display device according to an embodiment. For example, FIG. 7 may illustrate another example of the display device taken along the line I-I′ in FIG. 2. A display device described with reference to FIG. 7 may be substantially the same as or like the display device described with reference to FIG. 3, except for an addition of an etch-stop layer. Accordingly, descriptions on elements which are substantially the same or similar to those in FIG. 3 will not be repeated.

Referring to FIG. 7, a buffer layer BUF′ of a display device according to an embodiment may further include an etch-stop layer ES. The etch-stop layer ES may be disposed between the first portion BUF1a of the first buffer layer BUF1 and the second buffer layer BUF2 and between the second portion BUF1b of the first buffer layer BUF1 and the first active pattern A1.

An upper surface of the etch-stop layer ES located on the second portion BUF1b of the first buffer layer BUF1 and an upper surface of the second buffer layer BUF2 may be located on substantially the same level. The upper surface of the etch-stop layer ES located on the second portion BUF1b of the first buffer layer BUF1 and the upper surface of the second buffer layer BUF2 may correspond to an upper surface of the buffer layer BUF. Therefore, the buffer layer BUF may have a planarized upper surface.

In an embodiment, the etch-stop layer ES may include silicon nitride (SiNₓ). The etch-stop layer ES formed between the first buffer layer BUF1 and the second buffer layer BUF2 may include a material different from those of the silicon oxide layer formed in an upper portion of the first buffer layer BUF1 and the second buffer layer BUF2 including silicon oxide. In other words, the material of the etch-stop layer ES may be different from materials of the first buffer layer BUF1 and the second buffer layer BUF2 which are in contact with the etch-stop layer ES.

In an embodiment, a thickness of the etch-stop layer ES may be less than a thickness of the first buffer layer BUF1 and a thickness of the second buffer layer BUF2. As the thickness of the etch-stop layer ES may be relatively thin, an impact to the buffer layer BUF by the etch-stop layer ES including a material different from those of the silicon oxide layer of the first buffer layer BUF1 and the second buffer layer BUF2 may be minimized.

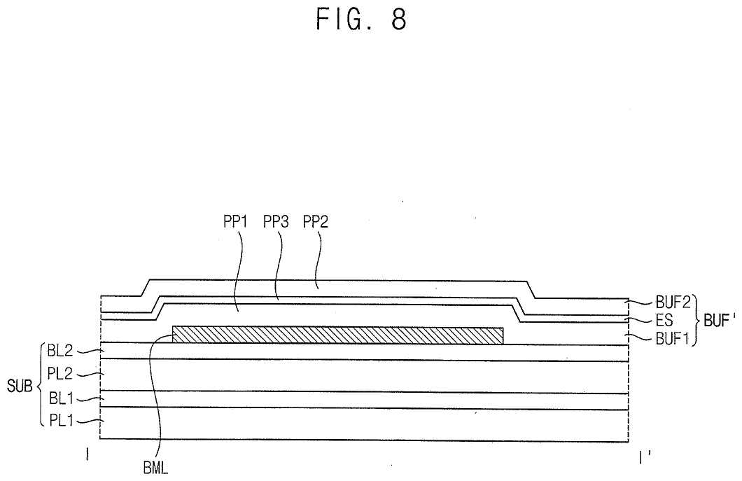

Hereinafter, a method of manufacturing a display device according to an embodiment will be described with reference to FIGS. 8 to 10. FIGS. 8-10 are cross-sectional views illustrating stages in a method of manufacturing the display device of FIG. 7. The method of manufacturing the display device described with reference to FIGS. 8 to 10 may be substantially the same as or similar to the method of manufacturing the display device described with reference to FIGS. 3 to 6, except for an additional formation of the etch-stop layer ES. Accordingly, descriptions of same or similar elements will not be repeated.

Referring to FIG. 8, the buffer layer BUF′ may be formed on the substrate SUB on which the metal layer BML is formed. The buffer layer BUF′ may include the first buffer layer BUF1, the etch-stop layer ES, and the second buffer layer BUF2.

The first buffer layer BUF1 may be deposited on the metal layer BML, and the etch-stop layer ES may be deposited on the first buffer layer BUF1. The etch-stop layer ES may be deposited on the first buffer layer BUF1 along a profile of the first buffer layer BUF1. Accordingly, the etch-stop layer ES may include a third protruding portion PP3 protruding upward along a profile of the first protruding portion PP1. The third protruding portion PP3 may overlap the first protruding portion PP1. For example, a silicon nitride layer may be deposited by chemical vapor deposition (CVD), sputtering, etc., on the buffer layer BUF1 to form the etch-stop layer ES. The etch-stop layer ES may be formed with a thickness less than that of the first buffer layer BUF1.

Then, the second buffer layer BUF2 may be deposited on the etch-stop layer ES. The second buffer layer BUF2 may be deposited on the etch-stop layer ES along a profile of the etch-stop layer ES. Accordingly, the second buffer layer BUF2 may include a second protruding portion PP2 protruding upward along a profile of the third protruding portion PP3. The second protruding portion PP2 may overlap the third protruding portion PP3.

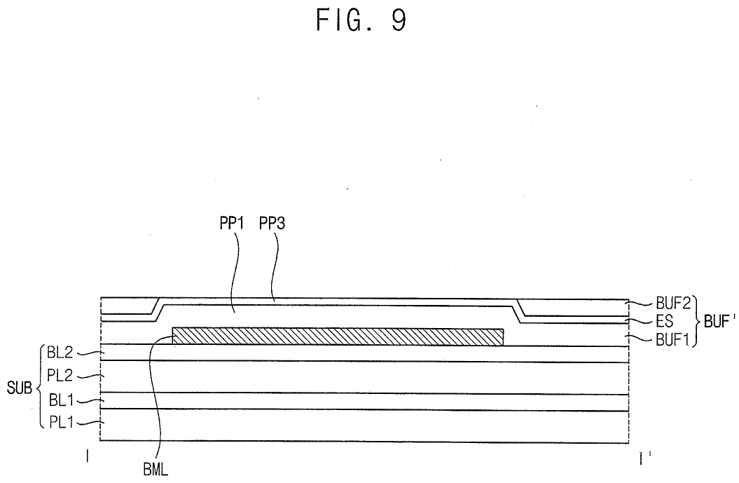

Referring to FIG. 9, an upper surface of the buffer layer BUF′ may be planarized. The second protruding portion PP2 of the second buffer layer BUF2 may be etched to planarize the upper surface of the buffer layer BUF′.

In the buffer layer BUF′, only the second protruding portion PP2 protruding upward may be etched, and a remaining portion of the buffer layer BUF′ may not be etched. In other words, in the second buffer layer BUF2, only the second protruding portion PP2 may be etched, and a remaining portion of the second buffer layer BUF2, an entirety of the etch-stop layer ES, and an entirety of the first buffer layer BUF1 may not be etched. In an embodiment, the second protruding portion PP2 protruding upward as well as an upper part of the third protruding portion PP3 of the etch-stop layer ES and an upper part of the remaining portion of the second buffer layer BUF2 may be partially etched.

As the etch-stop layer ES including silicon nitride different from those of the silicon oxide layer of the first buffer layer BUF1 and the second buffer layer BUF2 including silicon oxide may be formed between the silicon oxide layer of the first buffer layer BUF1 and the second buffer layer BUF2, the etch-stop layer ES may provide a reference for etching the buffer layer BUF in a process of planarizing the upper surface of the buffer layer BUF′. Only the second protruding portion PP2 of the second buffer layer BUF2 may be etched, and the first buffer layer BUF1 may not be etched. Therefore, an etching of the first buffer layer BUF1 may be prevented, and an impact to the first buffer layer BUF1 may be minimized in the process of the planarizing the buffer layer BUF′.

In an embodiment, a thickness of the etch-stop layer ES may be less than a thickness of the first buffer layer BUF1 and a thickness of the second buffer layer BUF2. As the thickness of the etch-stop layer ES may be relatively thin, an impact to the buffer layer BUF by the etch-stop layer ES including a material different from those of the silicon oxide layer of the first buffer layer BUF1 and the second buffer layer BUF2 may be minimized.

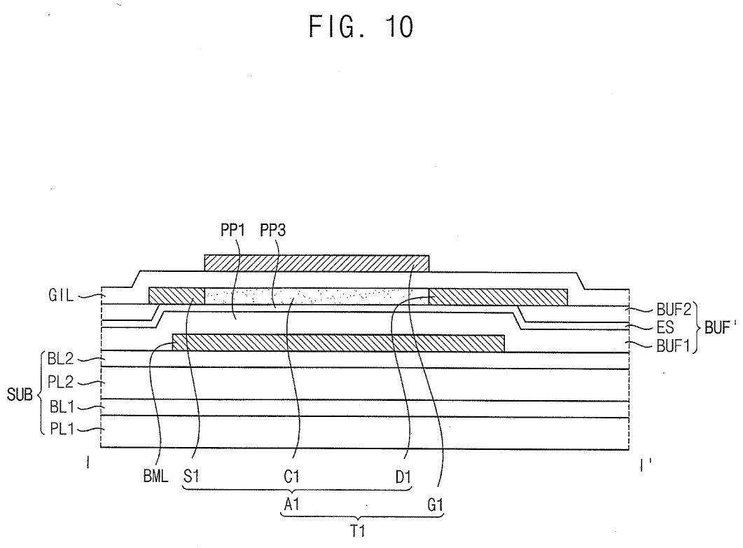

Referring to FIG. 10, the active patterns A1, A2, A3, A4, A5, A6, and A7, the gate insulation layer GIL, and the gate electrodes G1, G2, G3, G4, G5, G6, and G7 may be formed on the buffer layer BUF′ having the planarized upper surface.

The first active pattern A1 among the active patterns A1, A2, A3, A4, A5, A6, and A7 may be formed on the planarized upper surface of the buffer layer BUF′ with overlapping the metal layer BML. For example, a lower surface of the first active pattern A1 may be in contact with an upper surface of the third protruding portion PP3 of the etch-stop layer ES and an upper surface of the second buffer layer BUF2.

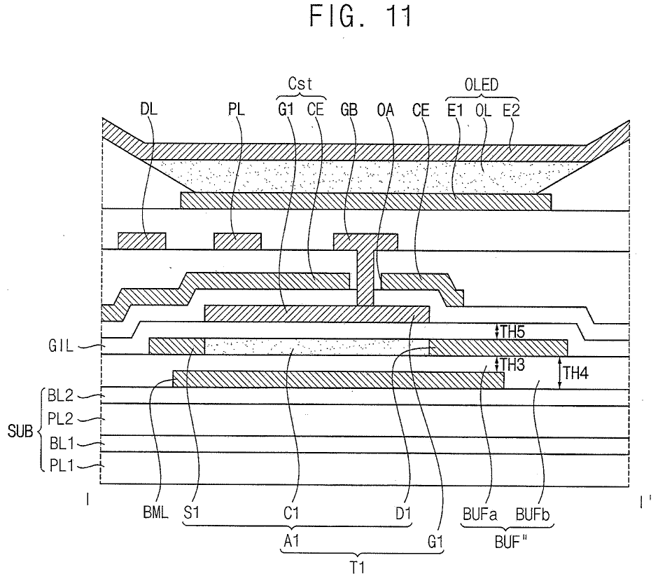

Hereinafter, a display device according to an embodiment will be described with reference to FIG. 11.

FIG. 11 is a cross-sectional view illustrating a display device according to an embodiment. For example, FIG. 11 may illustrate another example of the display device taken along the line I-I′ in FIG. 2. A display device described with reference to FIG. 11 may be substantially the same as or similar to the display device described with reference to FIG. 3, except for elements of the buffer layer BUF. Accordingly, descriptions of same or similar elements will not be repeated.

Referring to FIG. 11, a buffer layer BUF″ covering the metal layer BML may be disposed on the substrate SUB. The buffer layer BUF″ may have a planarized upper surface. The buffer layer BUF″ may include a first portion BUFa that overlaps the metal layer BML and a second portion BUFb that does not overlap the metal layer BML. The first portion BUFa of the buffer layer BUF may be disposed on an upper surface of the metal layer BML, and the second portion BUFb of the buffer layer BUF may be disposed on an upper surface of the substrate SUB.

A thickness TH3 of the first portion BUFa of the buffer layer BUF may be less than a thickness TH4 of the second portion BUFb of the buffer layer BUF. Because the upper surface of the buffer layer BUF formed on the substrate SUB having a planarized upper surface is planarized, the thickness TH3 of the first portion BUFa of the buffer layer BUF disposed on the upper surface of the metal layer BML may be less than the thickness TH4 of the second portion BUFb of the buffer layer BUF disposed on the upper surface of the substrate SUB.

In an embodiment, the thickness TH3 of the first portion BUFa of the buffer layer BUF may be less than or equal to a thickness TH5 of the gate insulation layer GIL. For example, the thickness TH5 of the gate insulation layer GIL may be in a range from about 1200 Å to about 1300 Å, and the thickness TH3 of the first portion BUFa of the buffer layer BUF may be less than or equal to the thickness TH5 of the gate insulation layer GIL. The first portion BUFa of the buffer layer BUF″ may function as a lower gate insulation layer between the metal layer BML that functions as a lower gate electrode and the first active pattern A1. The gate insulation layer GIL may function as an upper gate insulation layer between the first gate electrode G1 that functions as an upper gate electrode and the first active pattern A1. Since the thickness TH3 of the first portion BUFa of the buffer layer BUF″ is less than or equal to the thickness TH5 of the gate insulation layer GIL, controlling moving paths of electrons or holes of the first channel C1 of the first active pattern A1 depending on a voltage transmitted through the metal layer BML may be more facilitated.

The buffer layer BUF″ may prevent impurities from permeating through the substrate SUB, therefore, the buffer layer BUF″ may have a thickness greater than a predetermined magnitude. In the present embodiment, the metal layer BML may be formed under the first active pattern A1, and the metal layer BML may serve to prevent impurities from permeating into the active pattern A1. Accordingly, the buffer layer BUF may prevent impurities from permeating into the active pattern A1 although the first portion BUFa of the buffer layer BUF″ has a relatively thin thickness.

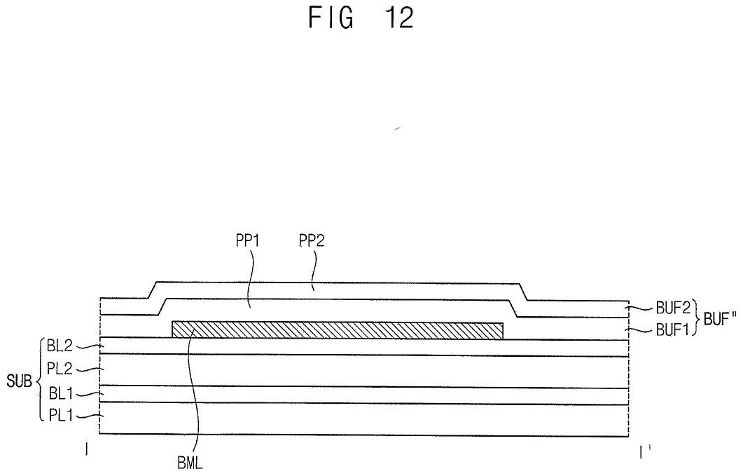

Hereinafter, a method of manufacturing a display device according to an embodiment will be described with reference to FIGS. 12 to 14.

FIGS. 12 to 14 are cross-sectional views illustrating stages in a method of manufacturing the display device of FIG. 11. The method of manufacturing a display device described with reference to FIGS. 12 to 14 may be substantially the same as or similar to the method of manufacturing the display device described with reference to FIGS. 3 to 6, except for planarizing the buffer layer BUF″. Accordingly, descriptions of same or similar elements will not be repeated.

Referring to FIG. 12, the buffer layer BUF″ covering the metal layer BML may be formed on the substrate SUB. The buffer layer BUF″ may include the first buffer layer BUF1 including the first protruding portion PP1 that overlaps the metal layer BML, and the second buffer layer BUF2 including the second protruding portion PP2 that overlaps the first protruding portion PP1.

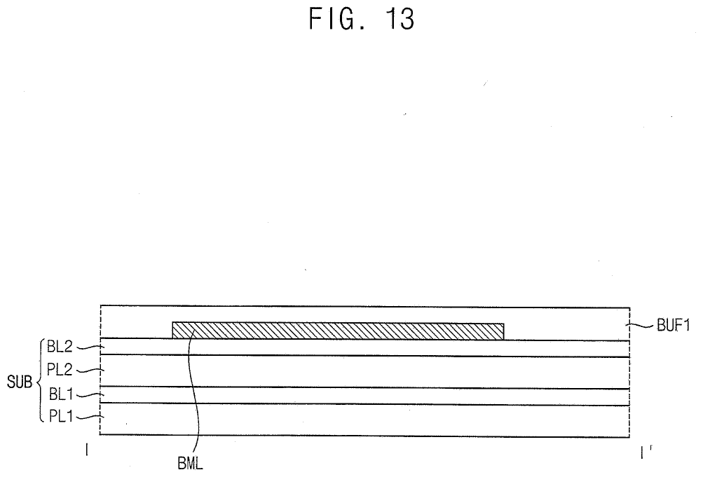

Referring to FIG. 13, an upper surface of the buffer layer BUF″ may be planarized. The second buffer layer BUF2 and the first protruding portion PP1 of the first buffer layer BUF1 may be etched to planarize the upper surface of the buffer layer BUF.

An entirety of the second buffer layer BUF2 and the first protruding portion PP1 of the buffer layer BUF1 may be etched, and a remaining portion of the first buffer layer BUF1 may not be etched and remain. The buffer layer BUF″ may be etched down from the upper surface of the second protruding portion PP2 by an addition of a thickness of the second buffer layer BUF2 and a thickness of the first protruding portion PP1.

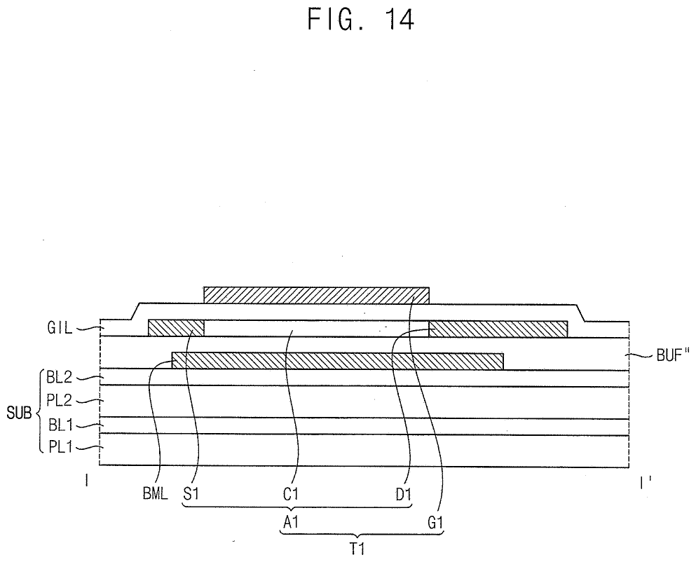

Referring to FIG. 14, the active patterns A1, A2, A3, A4, A5, A6, and A7, the gate insulation layer GIL, and the gate electrodes G1, G2, G3, G4, G5, G6, and G7 may be formed on the buffer layer BUF″ having the planarized upper surface. The first active pattern A1 among the active patterns A1, A2, A3, A4, A5, A6, and A7 may be formed on the planarized upper surface of the buffer layer BUF with overlapping the metal layer BML.

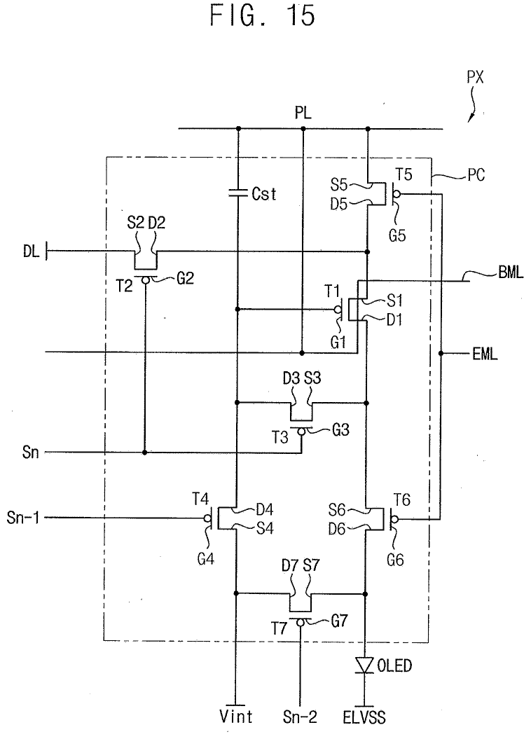

Hereinafter, display devices according to embodiments will be described with reference to FIGS. 15 to 20.

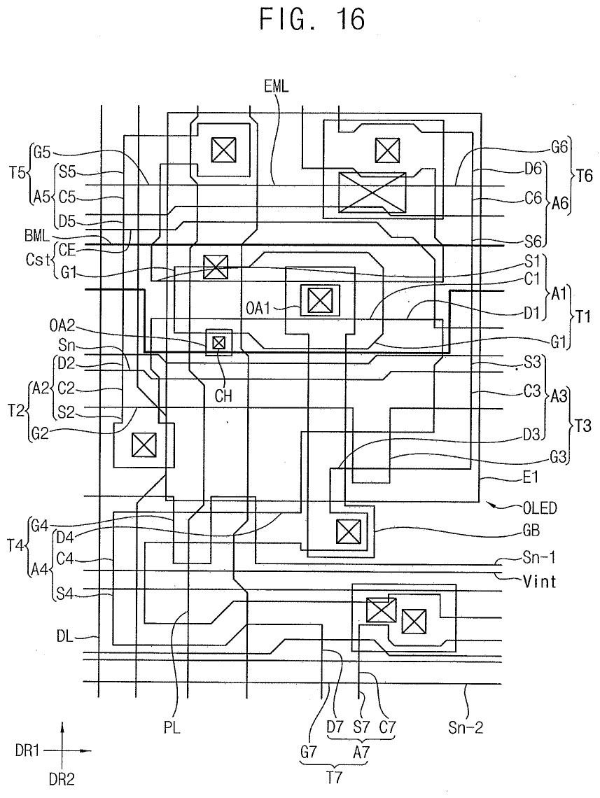

FIG. 15 is a circuit diagram illustrating a pixel of a display device according to an embodiment. FIG. 16 is a layout view illustrating the pixel in FIG. 15. The display device described with reference to FIGS. 15 and 16 may be substantially the same as or similar to the display device described with reference to FIGS. 1 and 2, except for a connection of the metal layer BML. Accordingly, descriptions of same or similar elements will not be repeated.

Referring to FIGS. 15 and 16, the metal layer BML may be connected to the driving voltage line PL. A driving voltage may be supplied from the driving voltage line PL to the metal layer BML.

In an embodiment, the metal layer BML may be connected to the driving voltage line PL inside the pixel PX. For example, the capacitor electrode CE may include an opening OA2 overlapping a crossing portion between the metal layer BML and the driving voltage line PL. A contact hole CH may be formed at a crossing portion between the metal layer BML and the driving voltage line PL in insulation layers located between the metal layer BML and the driving voltage line PL, and the metal layer BML may be in contact with the driving voltage line PL through the contact hole CH. In another embodiment, the metal layer BML may be connected to the driving voltage line PL outside the pixel PX.

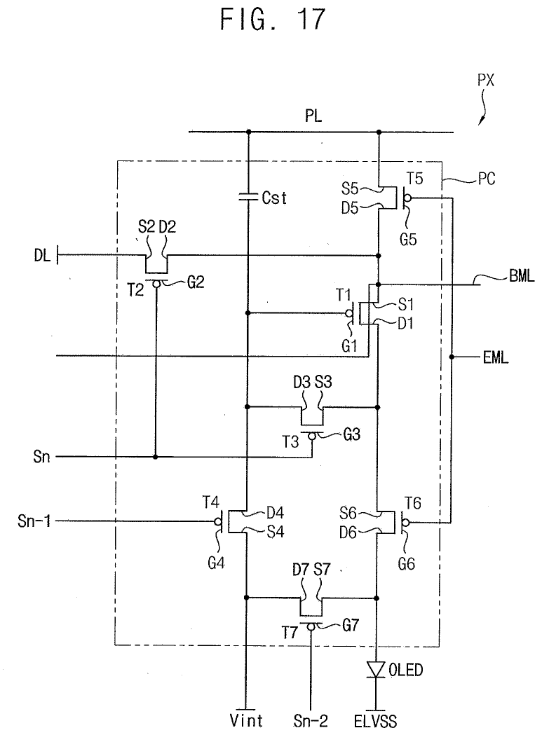

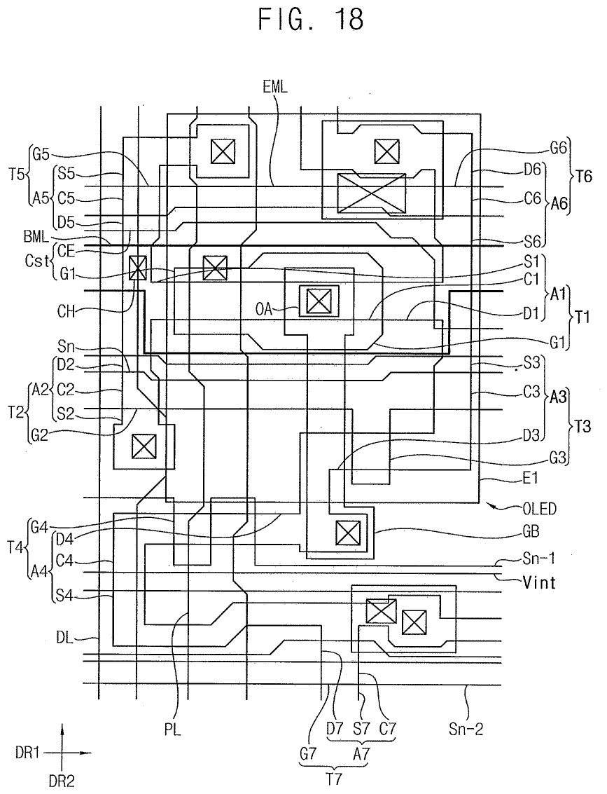

FIG. 17 is a circuit diagram illustrating a pixel of a display device according to an embodiment. FIG. 18 is a layout view illustrating the pixel in FIG. 17.

A display device described with reference to FIGS. 17 and 18 may be substantially the same as or similar to the display device described with reference to FIGS. 1 and 2, except for a connection of the metal layer BML. Accordingly, descriptions of same or similar elements will not be repeated.

Referring to FIGS. 17 and 18, the metal layer BML may be connected to the first source electrode S1 of the first thin film transistor T1. A voltage of the first source electrode S1 may be supplied to the metal layer BML.

The metal layer BML may be connected to the first source electrode S1 inside the pixel PX. For example, a contact hole CH may be formed at a crossing portion between the metal layer BML and the first source electrode S1 in the buffer layer BUF located between the metal layer BML and the first source electrode S1, and the metal layer BML may be in contact with the first source electrode S1 through the contact hole CH.

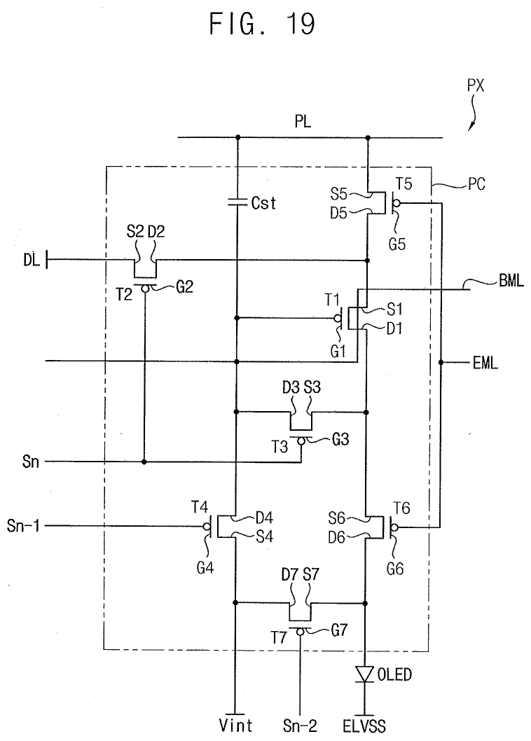

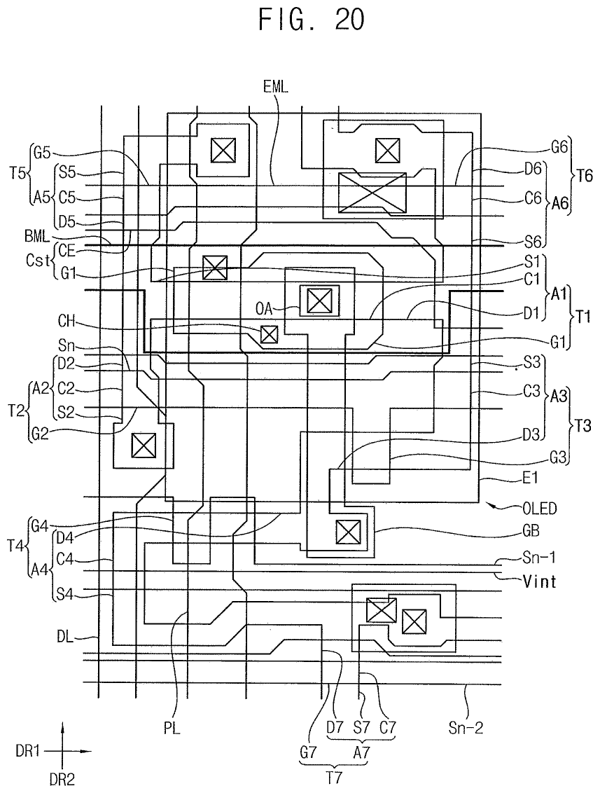

FIG. 19 is a circuit diagram illustrating a pixel of a display device according to an embodiment. FIG. 20 is a layout view illustrating the pixel in FIG. 19.

The display device described with reference to FIGS. 19 and 20 may be substantially the same as or similar to the display device described with reference to FIGS. 1 and 2, except for a connection of the metal layer BML. Accordingly, descriptions of same or similar elements will not be repeated.

Referring to FIGS. 19 and 20, the metal layer BML may be connected to the first gate electrode G1 of the first thin film transistor T1. A voltage of the first gate electrode G1 may be supplied to the metal layer BML.

The metal layer BML may be connected to the first gate electrode G1 inside the pixel PX. For example, a contact hole CH may be formed at a crossing portion between the metal layer BML and the first gate electrode G1 in the gate insulation layer GIL and the buffer layer BUF located between the metal layer BML and the first gate electrode G1, and the metal layer BML may be in contact with the first gate electrode G1 through the contact hole CH.

The display device according to the embodiments may be applied to a display device included in a computer, a notebook, a mobile phone, a smartphone, a smart pad, a PMP, a PDA, an MP3 player, or the like.

By way of summation and review, embodiments provide a display device in which characteristics of a thin film transistor are improved. Embodiments also provide a method of manufacturing a display device with improved characteristics of a thin film transistor.

That is, in the display device according to the embodiments, the upper surface of the buffer layer formed on the metal layer may be planarized. Accordingly, the active pattern disposed on the buffer layer may be planarized without a stepped portion, and characteristics of the thin film transistor including the active pattern may be improved.

In the method of manufacturing the display device according to the embodiments, after sequentially depositing the first buffer layer and the second buffer layer, at least the protruding portion of the second buffer layer may be etched to planarize the upper surface of the buffer layer. Accordingly, the active pattern disposed on the buffer layer may be evenly formed without a stepped portion, and characteristics of the thin film transistor including the active pattern may be improved.

Example embodiments have been disclosed herein, and although specific terms are employed, they are used and are to be interpreted in a generic and descriptive sense only and not for purpose of limitation. In some instances, as would be apparent to one of ordinary skill in the art as of the filing of the present application, features, characteristics, and/or elements described in connection with a particular embodiment may be used singly or in combination with features, characteristics, and/or elements described in connection with other embodiments unless otherwise specifically indicated. Accordingly, it will be understood by those of skill in the art that various changes in form and details may be made without departing from the spirit and scope of the present invention as set forth in the following claims.

What is claimed is:

1. A display device, comprising:
a substrate;
a metal layer on the substrate;
a buffer layer covering the metal layer and being on the substrate, the buffer layer having a planarized upper surface, and including:
a first buffer layer including a first portion not overlapping an upper surface of the metal layer and a second portion overlapping the upper surface of the metal layer, the second portion protruding upward from the first portion, and
a second buffer layer on the first portion of the first buffer layer;
an active pattern on the planarized upper surface of the buffer layer, the active pattern overlapping the metal layer;
a gate insulation layer on the active pattern;
a gate electrode on the gate insulation layer, the gate electrode overlapping the active pattern; and
an organic light emitting diode on the gate electrode.

2. The display device as claimed in claim 1, wherein a thickness of the metal layer is greater than or equal to a thickness of the gate electrode.

3. The display device as claimed in claim 1, wherein a material of the metal layer is a same as a material of the gate electrode.

4. The display device as claimed in claim 1, wherein an upper surface of the second portion of the first buffer layer and an upper surface of the second buffer layer are at a same level over the substrate.

5. The display device as claimed in claim 1, wherein the second buffer layer includes silicon oxide.

6. The display device as claimed in claim 1, wherein the buffer layer further includes an etch-stop layer between the first portion of the first buffer layer and the second buffer layer and between the second portion of the first buffer layer and the active pattern.

7. The display device as claimed in claim 6, wherein the etch-stop layer includes silicon nitride.

8. The display device as claimed in claim 6, wherein an upper surface of the etch-stop layer on the second portion of the first buffer layer and an upper surface of the second buffer layer are at a same level over the substrate.

9. The display device as claimed in claim 1, further comprising a driving voltage line on the gate electrode, the driving voltage line transmitting a driving voltage to the organic light emitting diode, and the metal layer being connected to the driving voltage line.

10. The display device as claimed in claim 1, wherein:
the active pattern includes a source electrode, a drain electrode, and a channel between the source electrode and the drain electrode, and
the metal layer is connected to the source electrode.

11. The display device as claimed in claim 1, wherein the metal layer is connected to the gate electrode.

12. The display device as claimed in claim 1, wherein a thickness of the metal layer is greater than or equal to 2500 Å.

13. A display device, comprising:
a substrate;
a metal layer on the substrate;
a buffer layer covering the metal layer and being on the substrate, the buffer layer having a planarized upper surface, and a thickness of a first portion of the buffer layer on an upper surface of the metal layer being less than a thickness of a second portion of the buffer layer not overlapping the upper surface of the metal layer;
an active pattern on the planarized upper surface of the buffer layer, the active pattern overlapping the metal layer;
a gate insulation layer on the active pattern;
a gate electrode on the gate insulation layer, the gate electrode overlapping the active pattern; and
an organic light emitting diode on the gate electrode.

14. The display device as claimed in claim 13, wherein a thickness of the first portion of the buffer layer is less than or equal to a thickness of the gate insulation layer.

15. The display device as claimed in claim 13, wherein a thickness of the metal layer is greater than or equal to a thickness of the gate electrode.

16. The display device as claimed in claim 13, wherein a material of the metal layer is a same as a material of the gate electrode.

17. The display device as claimed in claim 13, wherein a thickness of the first portion of the buffer layer is less than or equal to 1300 Å.

18. A method of manufacturing a display device, comprising:
forming a metal layer on a substrate;
forming a buffer layer on the substrate, the buffer layer covering the metal layer, and a portion of the buffer layer overlapping an upper surface of the metal layer being protruded;
planarizing an upper surface of the buffer layer;
forming an active pattern on the planarized upper surface of the buffer layer, the active pattern overlapping the metal layer;
forming a gate insulation layer on the active pattern;
forming a gate electrode on the gate insulation layer, the gate electrode overlapping the active pattern; and
forming an organic light emitting diode on the gate electrode,
wherein forming the buffer layer includes:
forming a first buffer layer on the metal layer, the first buffer layer including a first protruding portion overlapping the metal layer, and
forming a second buffer layer on the first buffer layer, the second buffer layer including a second protruding portion overlapping the first protruding portion, and
wherein planarizing the upper surface of the buffer layer includes etching at least the second protruding portion.

19. The method as claimed in claim 18, wherein planarizing the upper surface of the buffer layer includes etching only the second protruding portion.

20. The method as claimed in claim 18, wherein planarizing the upper surface of the buffer layer includes etching the second buffer layer and the first protruding portion.

21. The method as claimed in claim 18, wherein the upper surface of the buffer layer is planarized by a chemical mechanical polishing.

22. The method as claimed in claim 18, wherein forming the buffer layer further includes forming an etch-stop layer on the first buffer layer after forming the first buffer layer and before forming the second buffer layer.
